(19) United States
(12) Patent Application Publication
(10) Pub. No.: US 2021/0377633 A1
(43) Pub. Date: Dec. 2, 2021

(54) VOLTAGE DETECTION SYSTEM AND METHOD

(71) Applicant: SIGNIFY HOLDING B.V., EINDHOVEN (NL)

(72) Inventor: Hong CHEN, EINDHOVEN (NL)

(21) Appl. No.: 16/336,659

(22) PCT Filed: Sep. 25, 2017
(86) PCT No.: PCT/EP2017/074176

§ 371 Date: Mar. 26, 2019

(30) Foreign Application Priority Data
Sep. 29, 2016 (CN) PCT/CN2016/100852
Dec. 2, 2016 (EP) 16201868.3

(51) Int. Cl. H04Q 9/16; G01R 19/00

(52) U.S. Cl. CPC H04Q 9/16; H04Q 2209/84; G01R 19/0084

(57) ABSTRACT

A voltage sensing device is for sensing an operating voltage of a remote device, based on the measurement of time intervals associated with a chain of repeated communications with the device. The operating voltage of the remote device influences the rise time and fall times of signals sent by the remote device, and these differences in edge slopes of the signals influence the points in time at which signals are detected at the receiving end. Thus, the operating voltage influences a measured transit time of the signals.

### FIELD OF THE INVENTION

The invention relates to voltage detection for example for electronic circuits, and in particular relates to voltage detection remotely without the need for a local voltage sensor.

### BACKGROUND OF THE INVENTION

The voltage level of the supply voltage to a circuit is a key factor for system health, for example for digital lighting systems and other intelligent systems. A voltage fluctuation will impact on the performance of a digital system and will also influence the lifetime of components such as semiconductors and capacitors. A voltage monitoring function is thus more and more popular in intelligent systems.

Currently, the most typical solution is to provide a specific voltage measurement module in a circuit, and to transmit the measurement data to a control system. This solution has good performance since specific circuit designs are used. The measurement module may be based on an analog or a digital voltmeter. A digital voltmeter is widely used in smart systems and applications. It is for example based on an integrating analog-to-digital converter, so that dedicated IC and peripheral circuit have to be used. This solution has cost and reliability concerns due to the hardware complexity. Furthermore, the package size of a voltage measurement module will also be a problem when it needs to be provided within a small form factor system, such as compact luminaire.

US2009066258A1 discloses a streetlight controller for use in a street lighting system to monitor voltage in malls, arenas, indoor parking, underground roadways and underground parking. The controller has a sensor for sensing a light level from a lamp of a streetlight and another sensor for sensing a voltage level on a power line supplying power to the streetlight.

There is thus a need for a simple, low cost and flexible solution for measuring a component voltage.

### SUMMARY OF THE INVENTION

The invention is defined by the claims.

Examples in accordance with a first aspect of the invention provide a voltage sensing device for sensing an operating voltage of a remote device, comprising:

a controller for communicating electronically with the remote device over a communications interface,

wherein the controller is adapted to:
initiate a chain of repeated sequential communications between the voltage sensing device and the remote device;
measure a time interval associated with the chain of repeated communications; and
from the measured time interval, determine an operating voltage based on a relationship between voltage and time interval for the remote device.

This device is able to determine an operating voltage of a remote device with which it communicates. The operating voltage is for example a supply voltage of a controller of the remote device, and this operating voltage may be applied to other circuits within the remote device which are sensitive to the absolute voltage level, such as capacitor circuits, semiconductor components, etc. The operating voltage influences the rise time and fall times of signals sent by the remote device, and these differences in edge slopes of the signals travelling across the communications interface influence the points in time at which signals are detected at the receiving end. Thus, the operating voltage influences a measured transit time of the signals.

By measuring a time interval associated with a number of repeated sequential communications, it becomes possible to measure very small time interval values, which for example result from small changes in voltage. The remote device is “remote” in the sense that it has its own independent voltage source.

The approach does not need modification to the hardware of the remote device, since it simply relies on communication with the remote device. The operating voltage of the remote device is thus determined without any change in the existing product, in particular with no additional voltage sensor and associated circuits. The voltage sensing function is instead implemented based on signal communications and statistical analysis.

The time interval may be compared with a calibrated time interval corresponding to a known calibration operating voltage (so that changes are detected), or a calibration function (so that a mapping is provided).

The voltage detection is based on measuring the communication latency between an upstream unit and a downstream unit in order to deduce the voltage on the downstream unit. The approach is implemented by running a communications program in both units. The required computing capability is typically already present in the smart system, for example a smart luminaire.

The device may comprise a transmitter and a receiver, wherein the controller is adapted to:

control the transmitter to transmit an activation signal to the remote device for activating the remote device;

control the transmitter to transmit a number of challenge signals to the remote device, wherein the remote device is adapted to respond to the number of challenge signals by sending back a response signal per challenge signal to the voltage sensing device, each challenge signal and response signal together comprising one of said communications of said chain of repeated communications; and

determine time intervals present between transmissions of the challenge signals and receptions of the response signals.

In this way, the remote device is first activated, following which the challenge signals (i.e. ping signals) are sent and the responses are monitored. The activation signal means that an individual remote device within a network of such devices may be addressed.

The activation signal thus for example comprises an address for addressing one particular remote device.

The challenge signals and the response signals for example comprise square wave signals or step changes in voltage or short voltage pulses. The number of challenge signals and time periods comprises at least two challenge signals and time periods, preferably at least ten challenge signals and time periods, more preferably at least one hundred challenge signals and time periods etc. A time period can be expressed in time or in numbers of clock pulses or in any other way.

The controller is for example adapted to perform a calibration process at a known operating voltage or voltages of the remote device.

This calibration process thus provides a mapping between a change in time value (e.g. average time value or other statistical value based on the measured time periods) for the response to the challenge and a change in voltage.

The controller may be adapted to determine an actual operating voltage by applying the measured time interval to a stored function representing the voltage-time interval characteristics of the remote device.

The time interval is for example obtained based on a statistical analysis.

The statistical analysis may comprise:

a calculation of a mean value or any other value of the time intervals or functions thereof; or

an analysis of a distribution or any other spread of the time intervals or functions thereof.

These different possible analyses of the time periods may be used to assess the clock frequency of the remote device to a high accuracy. Functions of the time periods may for example comprise numbers of clock pulses of the clock signal of the voltage sensing device within the time periods or any other values derived from the time periods. The two options may be combined.

The device may comprise a lighting system controller.

It is then able to monitor the voltage of lighting units (e.g. luminaires) under its control, as part of the overall system monitoring function.

The invention also provides a voltage sensing system, comprising:

a voltage sensing device as defined above; and

a remote device connected to the voltage sensing device by the communications interface, wherein the remote device comprises:
a remote device controller which is adapted to respond immediately or else a preset number of clock cycles later to communications from the voltage sensing device.

The remote device thus responds to the ping messages in dependence on when the clock signal of the local controller is at the suitable transition.

When the voltage sensing device uses activation signals and challenge signals as defined above, the remote device may comprise:

a receiver adapted to receive the activation signal for activating the remote device and adapted to receive the number of challenge signals; and

a transmitter adapted to send back, in response to receptions of the number of challenge signals, the response signal per challenge signal to the voltage sensing device.

The remote device is thus first activated so that it then knows to respond to the ping messages of the voltage sensing device.

The remote device for example comprises a lighting load and associated local lighting controller.

Examples in accordance with another aspect of the invention provide a voltage sensing method, comprising:

initiating a chain of repeated sequential communications between a voltage sensing device having a controller and a remote device;

measuring a time interval associated with the chain of repeated communications; and

from the measured time interval, determining an operating voltage of the remote device based on a relationship between voltage and time interval for the remote device.

A calibration determination of the time interval with the remote device at one or more known operating voltages may be implemented.

The method may comprise:

controlling a transmitter of the voltage sensing device to transmit an activation signal to the remote device for activating the remote device;

controlling the transmitter to transmit a number of challenge signals to the remote device, wherein the remote device is adapted to respond to the number of challenge signals by sending back a response signal per challenge signal to the voltage sensing device, each challenge signal and response signal together comprising one of said communications of said chain of repeated communications; and

determining time intervals present between transmissions of the challenge signals and receptions of the response signals.

An actual operating voltage may be determined by applying the measured time interval to a stored function representing the voltage-time interval characteristics of the remote device.

The method may be implemented, at least in part, in software.

### BRIEF DESCRIPTION OF THE DRAWINGS

Examples of the invention will now be described in detail with reference to the accompanying drawings, in which:

FIG. 1 shows a network of a central control device and a set of remote load devices;

FIG. 2 shows a MOSFET circuit which represents a microcontroller communications interface;

FIG. 3 shows the waveform of a pulse signal;

FIG. 4 shows an example of the central controller which functions as a voltage measurement device;

FIG. 5 shows an example of a remote device which is a downstream unit;

FIG. 6 shows clock signals in a first situation;

In FIG. 7 shows clock signals in a second situation;

FIG. 8 shows distributions of time intervals;

FIG. 9 shows a downstream voltage and the time expense of the signal propagation;

FIG. 10 shows a plot of the real data of voltage versus time and a curve of a formula for a particular device;

FIG. 11 shows a voltage sensing method; and

FIG. 12 shows a general computer architecture suitable for implementing the controllers used in the system.

### DETAILED DESCRIPTION OF THE EMBODIMENTS

The invention provides a voltage sensing device for sensing an operating voltage of a remote device, based on the measurement of time intervals associated with a chain of repeated communications with the device. The operating voltage of the remote device influences the rise time and fall times of signals sent by the remote device, and these differences in edge slopes of the signals influence the points in time at which signals are detected at the receiving end. Thus, the operating voltage influences a measured transit time of the signals.

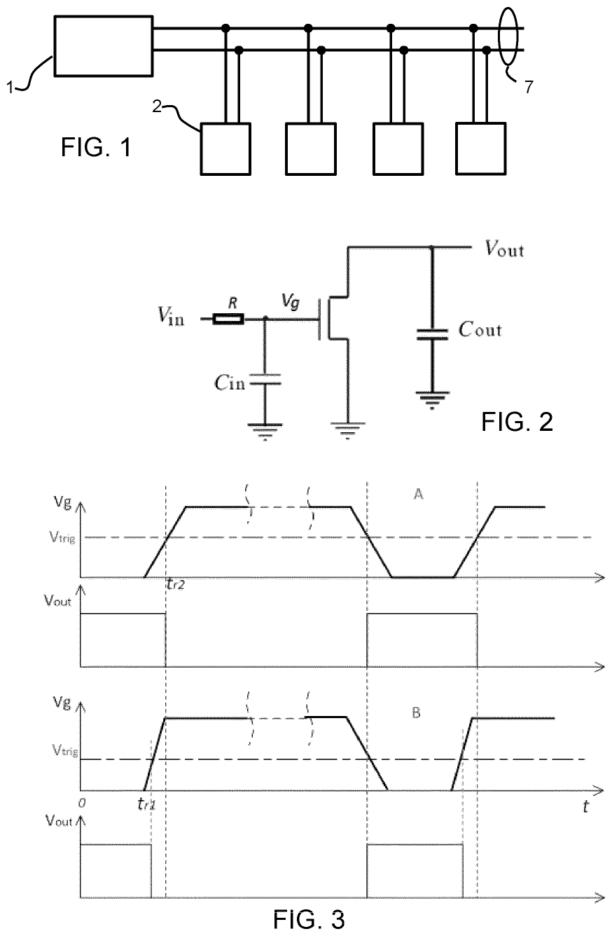

FIG. 1 shows a network of a central control device 1 such as a segment controller and a set of remote load devices 2. The central control device 1 controls and communicates with the remote load devices 2 over a communication interface, in particular a bus 7.

In one example, the overall system is a lighting system, in which the central control device is a main (upstream) lighting controller and the remote devices are luminaires.

The invention makes use of communication between the central control unit 1 and the luminaires 2 by which the central controller functions as an interrogator and the luminaries function as responders.

In a regular networked lighting system of this type, the upstream central control unit, such as segment controller, is an existing part of the system. By providing software code within the existing software, additional communications functions may be realized. The control board, based on a controller, in particular a microcontroller, in each luminaire can function as a downstream responder also by using software modifications.

The central control unit 1 is responsible for sending signals to the luminaires 2, analyze data and output a voltage sensing result. The control board in each luminaire receives commands and signals from the central controller and sends back responding signals.

The luminaires typically receive power from a local power supply rather than over a cable from the central controller. This reduces material cost and prevents power loss caused by long power cables. As a result of the different power supply used by the upstream and downstream units, the downstream voltage is unknown to the upstream side.

The downstream component typically comprises a microcontroller formed using millions of MOSFETs (Metal-Oxide Semiconductor Field-Effect Transistors).

Approximately, the microcontroller communications interface may be regarded as a MOSFET circuit with an equivalent circuit as shown in FIG. 2. An input signal Vin is applied to the gate through a gate resistor R to generate a gate voltage Vg. The output voltage Vout appears at the output (drain). There are several parasitic capacitances between the gate, source and drain approximated by the input and output capacitors Cin, Cout. A higher input voltage Vin cause faster charging for the gate capacitor Cin. Therefore the duration of the signal Vout reduces. The gate voltage charges with timing dictated by an RC time constant.

Assuming that the gate threshold voltage (at which the MOSFET will turn on) is Vtrig, then the quantity of electric charge is:

Q=Cj*Vtrig=I*t

Cj is a capacitance representing junction capacitances in the device.

Since I=V(t)/R , t=Q*R/V(t).

Thus, there is an inverse relation between t and V. A higher voltage means a small rise time (a steeper rise slope) of the gate voltage Vg, which changes the duration of a high output signal Vout.

A line communication signal comprises a series of signal pulses at a fixed frequency. As shown in FIG. 3, the waveform of a pulse single is not a rectangle but a trapezoid. The rising edge of a pulse is not sharp. FIG. 3 shows the output voltage Vout and the gate voltage Vg for gate voltages with different rise slopes. These different rise slopes are based on a capacitance model of the microcontroller communications interface. The waveforms are for an inverting gate, in that a high gate signal pulls low the drain.

This invention is thus based on the recognition that a variable voltage at the downstream controller has an impact on the communication signal. A signal disturbance can thus be measured at the upstream unit in order to derive the voltage.

A timer may conceptually be used to measure the signal transmission time from the downstream side to the upstream side. The signal falling edge in Vout may be used as a stop. The time expense in waiting for the trigger voltage to be reached is smaller than before if the voltage applied at the downstream side is increased.

With reference to FIG. 3, the time difference is tr2-tr1. By measuring this time difference, the voltage change can be deduced.

The voltage change may for example be derived from a formula which models the relationship, such as:

V=a/(TD+b)+c.

Here, V is the voltage, TD is the time delay measured by the central control device and a, b and c are parameters obtained by modeling or from data sheets for the remote load device. For example, in one analysis, values have been obtained of a=165.7, b=62.26, c=617.61.

The time difference for a single transition is too small to measure accurately. It is for example of the order of a few nanoseconds. Instead, a method is provided based on a chain of repeated sequential communications between the voltage sensing device and the remote device. This process is described below.

The operation voltage of the upstream controller is assumed to be fixed and stable. The method also requires a stable communication path between the upstream and downstream units. A calibration is also carried out before the voltage measurement. The calibration is used to set the downstream voltage to a known value so that a reference signal propagation time can be measured at the upstream side. Time variance caused by an unstable downstream voltage can then be measured in the manner explained below.

Of cause, it is a challenge to measure the time difference because time variance is very small caused by voltage changes.

The accurate time measurement method involves operating the microcontroller in the luminaire 2 in a responder mode. The upstream controller 1 sends a ping challenge signal and measures the time expense of responding from the remote downstream unit. By repeating this process hundreds or thousands of times, the time expense can be derived using statistical tools with high accuracy.

This ping challenge and the response together form a signal communication event between the upstream and downstream controller. The repetition of the process then forms a chain of communications. This overall chain forms a measurement period. Each communication can be based on any outward message which is sent from the upstream controller to the downstream controller and return message which is sent back from the downstream controller to the upstream controller. The timing at which a message is sent (and finally received) by the upstream controller will depend on signal slopes which arise in the downstream controller.

The central controller for example operates with a clock signal having a relatively high clock speed, whereas the controllers of the luminaires operate with a clock signal having a relatively low clock speed. As a result, an amount of delay which is introduced by the luminaire controller may be more significant compared to the central controller clock frequency. This delay may show relatively large fluctuations. The central device can measure the time interval associated with this delay relatively precisely because of the faster clock signal whereas the luminaire may react to a reception of a challenge signal by sending a response signal relatively soon or relatively late, depending on whether the edges or levels of both clock signals of both devices in each case match or not.

A time interval of a single signal will not give much information about the rise or fall times of the luminaire controller, whereas the use of multiple challenge and response signals enables statistical analysis to be used to determine the luminaire voltage which depends on these rise or fall times.

The time interval which is measured is for example the length of time, expressed as the number of clock periods of the faster upstream controller clock, which has elapsed between the upstream controller clock signal edge which corresponds to the sending of the challenge signal and upstream controller clock signal edge which corresponds to the receipt of the response signal. As a result, all timing measurements may be made at the upstream controller based on the faster upstream controller clock. The whole timing process is thus controlled from the upstream side with the downstream controller simply following a dumb response routine.

Note that the time interval may include fixed time durations not related to the rise (or fall) times, for example propagation delays. Furthermore, it is not essential that the response is provided immediately to the challenge signal. There may be a delay of a number of clock cycles at the downstream controller, to process the challenge and generate the response. These elements do not change the operation of the method. The calibration at known voltage takes account of these elements.

This process will now be described in more detail.

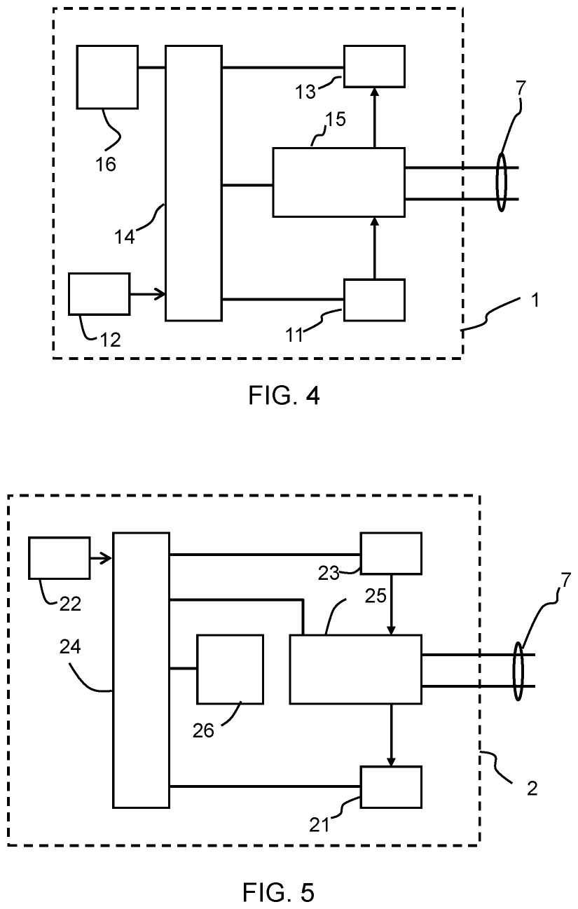

FIG. 4 shows an example of the central controller 1 which functions as a voltage measurement device. This is an upstream unit.

The voltage measurement device 1 comprises a transceiver 11,13 for transmitting and receiving signals. A transmitter 11 is configured to transmit an activation signal to a remote device 2 for activating this remote device 2. The transmitter part 11 is also configured to transmit a number of challenge signals to the activated remote device 2. Such an activated remote device 2 is configured to respond to the number of challenge signals by sending back a response signal per challenge signal to the voltage measurement device 1. A receiver 13 of the voltage measurement device 1 is configured to receive the response signals from the activated remote device 2. The voltage measurement device 1 further comprises a controller 14 configured to determine time intervals present between transmissions of the challenge signals on the one hand and receptions of the response signals on the other hand. The controller 14 is further configured to derive a voltage from an analysis of the time intervals.

These response signals are not to be confused with reflection signals that result from impedance mismatching. The activation signal may for example comprise an address for addressing the remote device 2.

Usually, the analysis comprises a statistical analysis, such as for example a calculation of a mean value or any other value of the time intervals or functions thereof or such as for example an analysis of a distribution or any other spread of the time intervals or functions thereof, or such as for example a determination of a minimum value of the time intervals or functions thereof.

The transmitter 11 is configured to transmit the number of challenge signals periodically or randomly.

In FIG. 4, the transceiver 11, 13 is coupled to a bus interface 15, that is further coupled to the communication bus 7, but alternatively the bus interface 15 could be left out or integrated into said transceiver 11, 13. A controller 14 controls and/or communicates with the transmitter 11 and the receiver 13 and the bus interface 15, and further controls and/or communicates with a user interface 16. An example of such a controller 14 is a processor/memory combination that is operated with a clock signal having a relatively high clock speed, like for example 10 MHz or 100 MHz etc. The (first) crystal oscillator 12 of the central controller is also shown schematically.

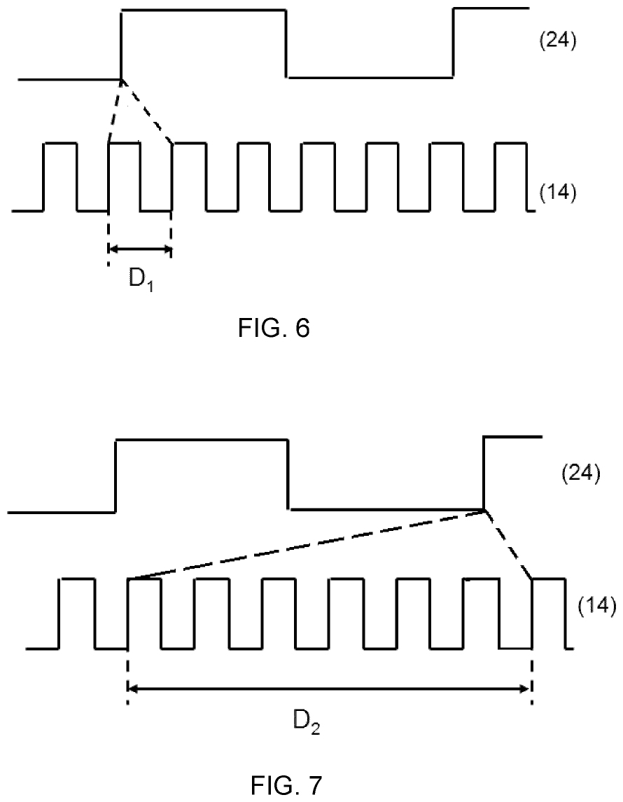

FIG. 5 shows an example of a remote device 2. This is a downstream unit. The remote device 2 is configured to be interrogated by the voltage measurement device 1 as shown in FIG. 7 and comprises a transceiver 21, 23. A receiver 21 of the transceiver is configured to receive the activation signal from the voltage measurement device 1 for activating this remote device 2. The receiver 21 is also configured to receive the number of challenge signals from the voltage measurement device 1. The transmitter 23 of the transceiver of the remote device 2 is configured to send back, in response to receptions of the number of challenge signals, the response signal per challenge signal to the voltage measurement device 1. The remote device 2 may further comprise a load 26 such as for example a light dot or a lamp.

In FIG. 5, the receiver 21 and the transmitter 23 are coupled to a bus interface 25, that is further coupled to the communication bus 7, but alternatively the bus interface 15 could be left out or integrated into said receiver 21 and said transmitter 23.

A controller 24 controls and/or communicates with the receiver 21 and the transmitter 23 and the bus interface 25 and the load 26. An example of such a controller 24 is a processor/memory combination that is operated with a clock signal having a relatively low clock speed, like for example 1 MHz or 10 MHz etc. Usually, the relatively high clock speed of the clock signal of the controller 14 is higher than the relatively low clock speed of the clock signal of the controller 24. The (second) crystal oscillator 22 of the remote device is also shown schematically.

In FIG. 6, clock signals are shown in a first situation. In this first situation, a rising edge of the clock signal having the relatively high clock speed of the controller 14 is situated in time just sufficiently before a rising edge of the clock signal having the relatively low clock speed of the controller 24. As a result, the remote device 2 can in one example react immediately to the challenge signal from the voltage measurement device 1 by sending back the response signal to the voltage measurement device 1. A minimum value of a total delay D1 is a duration of a time interval present between a transmission of the challenge signal and a reception of the response signal, at the next rising edge of the controller clock signal.

In FIG. 7, clock signals are shown in a second situation. In this second situation, a rising edge of the clock signal having the relatively high clock speed of the controller 14 is situated in time insufficiently before the first shown rising edge of the clock signal having the relatively low clock speed of the controller 24. As a result, the remote device 2 can only react later to the challenge signal from the voltage measurement device 1 by sending back the response signal to the voltage measurement device 1 shortly after the next rising edge of the clock signal having the relatively low clock speed of the controller 24. A maximum value in this scenario of a total delay D2 is a duration of a time interval present between a transmission of the challenge signal and a reception of the response signal at the next rising edge.

This assumes the execution of signals by the upstream controller is trigged by the rising edge of clock signal. Of course, the triggers could equally be at the falling edge of the clock signals.

This maximum delay (as a number of the faster clock cycles) in particular will depend on intervals of the slower clock signal, which is impacted by the rise time of the gate signal (Vg).

Instead of responding immediately, the response may be made after a fixed number (which may be 1 or more) of clock cycles of the remote device.

The above analysis is based on the assumption that the time expense of the signal propagation on the cable between the upstream unit and the downstream unit is zero.

Actually the time expense caused by cable is not zero but it does not affect the analysis above because it is a fixed number for a given cable length. The time expense caused by the cable is thus cancelled by the algorithm as explained further below.

By sending a large set of challenges and responses, a statistically significant set is obtained. For example, the average number of faster clock pulses for a large sample of data will give an accurate indicator of the period of the slower clock period.

As can be seen from the example above, one time interval will not give much information about the signal timing (hence voltage) at a remote device because of the amount of possible variation. By analysis of a number of time intervals, the timing information for the remote device can be determined much better. The number of challenge signals and time intervals comprises at least two challenge signals and time intervals, preferably at least ten challenge signals and time intervals, more preferably at least one hundred challenge signals and time intervals etc. There may even be 1000 of more challenges and responses. For a sufficient number of challenge signals and time intervals, the set of time intervals durations will satisfy an even distribution.

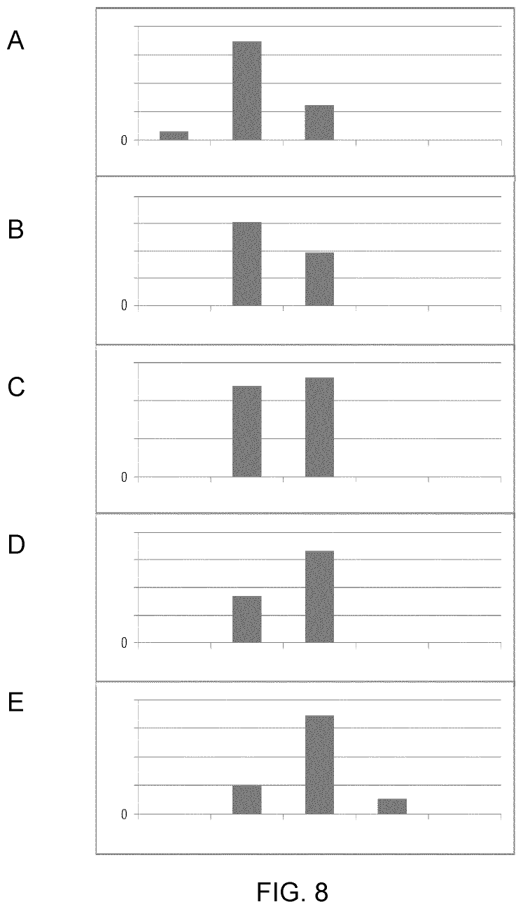

FIG. 8 shows distributions of time intervals. FIGS. 8A to 8E show distributions of time intervals for a remote device which is operating at different (increasing) rise times.

Clearly, from FIG. 8A to FIG. 8E, the distributions are shifting to the right.

For the time intervals related to FIG. 8A, a calculation of a mean value of the time intervals will result in a smaller value than a similar calculation for the time intervals related to FIG. 8B and so on. For the time intervals related to FIG. 8A, a determination of a minimum value of the time intervals will result in a smaller value than a similar calculation for the time intervals related to FIG. 8B and so on due to the slower processing of the respond signal.

The distribution or any other spread of the time intervals may be used for analysis.

An example of the signal processing that may be applied will now be presented in more detail.

A calibration stage is first carried out. As a minimum, the calibration takes place at a known voltage at the downstream unit. However, it may involve taking measurements at two or more known voltages.

At the (or each) calibration voltage V1 a number of steps are carried out:

Step 1: The upstream unit sends a command with a specific address to activate a selected unit at downstream side. The specific downstream unit transitions to a responder mode and then waits for a “ping” signal from the upstream unit. Other downstream units are still in their “idle” state .

Step 2: The upstream unit sends a pulse as a “ping signal” to the specific downstream unit, and starts a timer at same time.

Step 3: The downstream unit receives the “ping” signal and sends back a pulse immediately.

Step 4: The upstream unit stops the timer at once when it detect the response pulse from the downstream side.

Step 5: The upstream unit saves the timer's readout in a register for further calculation. The timer is then reset for the next action.

Step 6: The steps 2 to 5 are repeated hundreds or thousands of times.

Step 7: The average time value is calculated based on the data in the register.

Step 8: The final result is saved as reference data V_ref1 to be used for measurement.

After the calibration, the system is ready for use.

This involves performing a voltage measurement, namely when there is an unknown voltage at the downstream side.

Steps 2 to 7 above are repeated to obtain an average time value t1 measured.

A function of voltage versus time delay is based on factory information about the specific device, namely the specific device (e.g. part number) combined with the process technology used.

The calibration step enables the voltage versus time penalty function (known from the manufacturer) to be correctly mapped to the actual device, based on one (or more) known points along that function. Deviations from that known point are measured, so that the all fixed delays within the system are compensated.

As explained above, a time measurement at the upstream unit is thus able to be analyzed to determine a voltage at the remote unit. The upstream unit has a higher clock frequency, making it more suitable for measuring time intervals. However, although the clock frequency in the upstream unit is higher than the clock frequency in the downstream unit, it still does not have enough resolution to measure directly (i.e. see) the time difference caused by voltage changes. The way in which the use of multiple measurements addresses this issue will now be explained further.

For example if a 16 MHz crystal is used for for the upstream controller, the ultimate resolution for a timer in the upstream unit is 1/16 Mhz=62.5 ns. The timer in the control unit cannot recognize a time variance if is less than 62.5 ns.

The time variance caused by voltage fluctuations is of the same order of magnitude or smaller, for example around 30 ns per Volt.

The time interval which is measured by the timer in the controller may for example be 500 clock cycles. Even if the voltage changes, the readout of the timer may still be the same even though the time expense is fractionally changed.

One option is to increase the timer frequency to giver higher resolution but this is costly. The approach above is instead based on use of the statistical probability distribution. In particular, the readout signal from the timer should meet certain distribution rules relating to time measurement. If there is minor change to the time expense which is caused by voltage changes, the distribution curve of the readout signal from the timer will change as well. For example, if 1000 timing measurements are taken at voltage V1, all close to 500 clock cycles, the frequency density of the timing measurements may be as shown below:

| | | | |
|---|---|---|---|
| Timer readout | 499 | 500 | 501 |
| Frequency | 100 | 800 | 100 |

If the voltage is changed to V2 and assume the time expense increases by 2 nanoseconds. For 1000 time measurements, the data from the timer may be changed as shown below:

| | | | |
|---|---|---|---|
| Timer readout | 499 | 500 | 501 |
| Frequency | 90 | 801 | 109 |

This provides a shift to the increasing values, for example as shown in FIG. 8. The readout is still within the range 499 to 501 but the change in distribution reflects the change in voltage.

It has been shown that this approach enables the time change to be distinguished with nanosecond accuracy even with a 16 MHz clock. For example, the average timer value has increased from 500.000 to 500.019. The average value may be used, or measures of spread or other statistical measures may be used to obtain a more accurate representative timer value, which can then be converted to voltage.

The controller 24 may introduce a delay for example owing to the fact that it needs several clock periods to detect the challenge signal and to instruct the response signal to be sent back. The controller 14 may also introduce a delay for example owing to the fact that it needs several clock periods to prepare the challenge signal and/or that it needs several clock periods to detect the response signal and/or that it needs several clock periods to determine the time intervals. These introduced delays are taken into account in determining the voltage, in particular if computations are based on a calibration time and calibration voltage.

The method described above has been tested experimentally. The voltage of an upstream controller was set to 5V and the downstream voltage was adjusted from from 2.5V to 5.7V and back to 2.5V linearly.

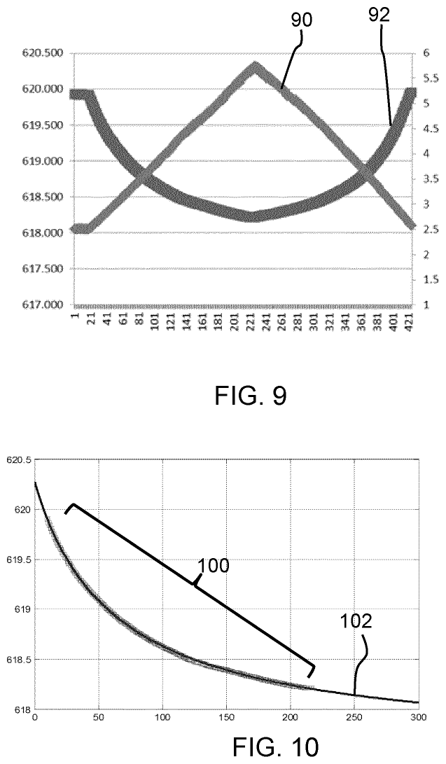

FIG. 9 shows downstream voltage (plot 90) and the time expense of the signal propagation (plot 92). The data from the upstream controller is not measured in real time but is a count number from the timer in the upstream controller. The left y-axis the timer readout and the right y-axis is the voltage at the downstream controller.

The time expense can be seen to be non-linear but the voltage change is linear. This matches the findings above. FIG. 10 shows a plot of the real data as plot 100 and plot 102 is a curve of a formula for the particular device, based on the technical data provided by the manufacturer. The real data matches the formula very well. It shows the strict inverse relationship between V and t. Thus, based on a measured time expense, the voltage can be deduced using a strict mathematical algorithm. The ultimate resolution of the voltage measurement in the experiment conducted was found to be 50 millivolts.

The method described above basically detects timing changes at the remote device. A supply voltage change causes rise times (and/or fall times) to change, which in turn are detected as timing changes. Other changes may also provide timing changes. For example, timing changes will result if there are variations in frequency at the remote device. These may be brought about by temperature fluctuations. Such temperature fluctuations are generally smaller and slower than fluctuations caused by voltage.

Thus, the timing information may be processed further in order to ensure voltage changes are responsible, for example by applying high pass filtering to the measured changes. Voltage fluctuations may be discriminated from other fluctuations based on the frequency and the duty circle of the received signal. At the clock side, the frequency is fixed, and the waveform is symmetrical, so that the time at a high level is the same as the time at a low level. The voltage fluctuation will impact the slope of signal due to the gate capacitor of the transistor, as seen in FIG. 3. This finally causes a duty cycle change at the output voltage signal although the frequency (period) is the same as before. Frequency changes (for example caused by temperature) will instead maintain the same duty cycle.

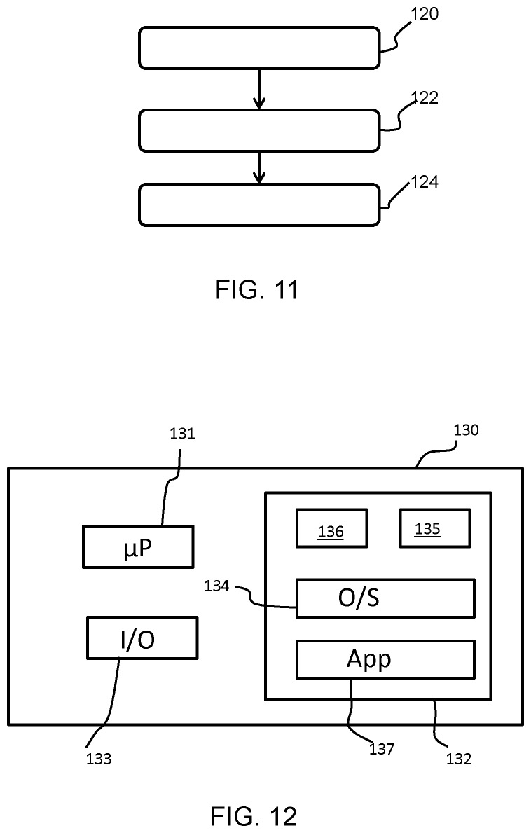

FIG. 11 shows a voltage sensing method. In step 120 a chain of repeated sequential communications is initiated between a voltage sensing device and a remote device.

In step 122, a time interval associated with the chain of repeated communications is measured at the voltage sensing device. This time interval may be a value derived from the set of individual measurements, such as an average value, or a value which takes account of the degree of spread, or a value which takes account both of an average value and a degree of spread.

In step 124 l a voltage at the remote device is determined from the time interval based on knowledge of the time-voltage characteristics of the remote device.

The method may include a calibration step in which the remote device is known to be at a particular voltage. This provides reference information for calibrating the subsequent voltage measurements.

The system described above makes use of a controller/processor for processing data to determine the voltage.

FIG. 12 illustrates an example of a computer 130 for implementing the controller or processor described above. The computer 130 includes, but is not limited to, PCs, workstations, laptops,

PDAs, palm devices, servers, storages, and the like. Generally, in terms of hardware architecture, the computer 130 may include one or more processors 131, memory 132, and one or more I/O devices 133 that are communicatively coupled via a local interface (not shown). The local interface can be, for example but not limited to, one or more buses or other wired or wireless connections, as is known in the art. The local interface may have additional elements, such as controllers, buffers (caches), drivers, repeaters, and receivers, to enable communications. Further, the local interface may include address, control, and/or data connections to enable appropriate communications among the aforementioned components.

The processor 131 is a hardware device for executing software that can be stored in the memory 132. The processor 131 can be virtually any custom made or commercially available processor, a central processing unit (CPU), a digital signal processor (DSP), or an auxiliary processor among several processors associated with the computer 130, and the processor 131 may be a semiconductor based microprocessor (in the form of a microchip) or a microprocessor. The memory 132 can include any one or combination of volatile memory elements (e.g., random access memory (RAM), such as dynamic random access memory (DRAM), static random access memory (SRAM), etc.) and non-volatile memory elements (e.g., ROM, erasable programmable read only memory (EPROM), electronically erasable programmable read only memory (EEPROM), programmable read only memory (PROM), tape, compact disc read only memory (CD-ROM), disk, diskette, cartridge, cassette or the like, etc.). Moreover, the memory 132 may incorporate electronic, magnetic, optical, and/or other types of storage media. Note that the memory 132 can have a distributed architecture, where various components are situated remote from one another, but can be accessed by the processor 131.

The software in the memory 132 may include one or more separate programs, each of which comprises an ordered listing of executable instructions for implementing logical functions. The software in the memory 132 includes a suitable operating system (O/S) 134, compiler 135, source code 136, and one or more applications 137 in accordance with exemplary embodiments.

The application 137 comprises numerous functional components such as computational units, logic, functional units, processes, operations, virtual entities, and/or modules.

The operating system 134 controls the execution of computer programs, and provides scheduling, input-output control, file and data management, memory management, and communication control and related services.

Application 137 may be a source program, executable program (object code), script, or any other entity comprising a set of instructions to be performed. When a source program, then the program is usually translated via a compiler (such as the compiler 135), assembler, interpreter, or the like, which may or may not be included within the memory 132, so as to operate properly in connection with the operating system 134. Furthermore, the application 137 can be written as an object oriented programming language, which has classes of data and methods, or a procedure programming language, which has routines, subroutines, and/or functions, for example but not limited to, C, C++, C#, Pascal, BASIC, API calls, HTML, XHTML, XML, ASP scripts, JavaScript, FORTRAN, COBOL, Perl, Java, ADA, .NET, and the like.

The I/O devices 133 may include input devices such as, for example but not limited to, a mouse, keyboard, scanner, microphone, camera, etc. Furthermore, the I/O devices 133 may also include output devices, for example but not limited to a printer, display, etc. Finally, the I/O devices 133 may further include devices that communicate both inputs and outputs, for instance but not limited to, a network interface controller (NIC) or modulator/demodulator (for accessing remote devices, other files, devices, systems, or a network), a radio frequency (RF) or other transceiver, a telephonic interface, a bridge, a router, etc. The I/O devices 133 also include components for communicating over various networks, such as the Internet or intranet.

When the computer 130 is in operation, the processor 131 is configured to execute software stored within the memory 132, to communicate data to and from the memory 132, and to generally control operations of the computer 130 pursuant to the software. The application 137 and the operating system 134 are read, in whole or in part, by the processor 131, perhaps buffered within the processor 131, and then executed.

When the application 137 is implemented in software it should be noted that the application 137 can be stored on virtually any computer readable medium for use by or in connection with any computer related system or method. In the context of this document, a computer readable medium may be an electronic, magnetic, optical, or other physical device or means that can contain or store a computer program for use by or in connection with a computer related system or method.

The invention thus provides a low cost statistical method to automatically obtain voltage information from a downstream based on signal propagation latency. This method using an existing controller but does not add new hardware. Since only a software update is needed in an intelligent system (such as a smart lighting system), it provides a low cost and highly reliable solution. The approach can be used in any system which the same topology with data communication between microcontroller systems.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. Any reference signs in the claims should not be construed as limiting the scope.

1. A voltage sensing device for sensing an operating voltage of a remote device, comprising:
a controller for communicating electronically with the remote device over a communications interface,
wherein the controller is adapted to:
initiate a chain of repeated sequential communications between the voltage sensing device and the remote device, each communication comprising transmission of a challenge signal to the remote device and reception of a response signal per challenge signal;
measure time intervals presenting between transmissions of challenge signals and receptions of the response signals associated with the chain of repeated communications; and
from the measured time intervals, determine an operating voltage based on a relationship between voltage and time interval for the remote device.

2. A device as claimed in claim 1, comprising a transmitter and a receiver, wherein the controller, is adapted to perform the flowing step before the step of initiating a chain of repeated sequential communications:
control the transmitter to transmit an activation signal to the remote device for activating the remote device.

3. A device as claimed in claim 2, wherein the controller is adapted to perform a calibration process at a known operating voltage or voltages of the remote device.

4. A device as claimed in claim 1, wherein the controller is adapted to determine an actual operating voltage by applying the measured time interval to a stored function representing the voltage-time interval characteristics of the remote device.

5. A device as claimed in claim 1, wherein the time interval is obtained based on a statistical analysis.

6. A device as claimed in claim 5, wherein the statistical analysis comprises:
a calculation of a mean value or any other value of the time intervals or functions thereof; or
an analysis of a distribution or any other spread of the time intervals or functions thereof.

7. A device as claimed claim 1, comprising a lighting system controller.

8. A voltage sensing system, comprising:
a voltage sensing device as claimed in claim 1;
a remote device connected to the voltage sensing device by the communications interface, wherein the remote device comprises:
a remote device controller which is adapted to respond immediately or else a preset number of clock cycles later to communications from the voltage sensing device.

9. A system as claimed in claim 8, comprising a voltage sensing device, wherein the remote device comprises:
a receiver adapted to receive the activation signal for activating the remote device and adapted to receive the number of challenge signals; and
a transmitter adapted to send back, in response to receptions of the number of challenge signals, the response signal per challenge signal to the voltage sensing device.

10. A system as claimed in claim 8, wherein the remote device comprises a lighting load and associated local lighting controller.

11. A voltage sensing method, comprising:
initiating a chain of repeated sequential communications between a voltage sensing device having a controller and a remote device, each communication comprising transmission of a challenge signal to the remote device and reception of a response signal per challenge signal;
measuring time intervals presenting between transmissions of challenge signals and receptions of the response signals associated with the chain of repeated communications; and
from the measured time interval, determining an operating voltage of the remote device based on a relationship between voltage and time interval for the remote device.

12. A method as claimed in claim 11, comprising implementing a calibration determination of the time interval with the remote device at one or more known operating voltages.

13. A method as claimed in claim 11, comprising:
controlling a transmitter of the voltage sensing device to transmit an activation signal to the remote device for activating the remote device.

14. A method as claimed in claim 11, comprising determining an actual operating voltage by applying the measured time interval to a stored function representing the voltage-time interval characteristics of the remote device.

15. A computer program comprising code means which is adapted, when said program is run on a computer, to implement the method of claim 11.
